(19) United States
(12) Patent Application Publication
(10) Pub. No.: US 2014/0009897 A1
(43) Pub. Date: Jan. 9, 2014

(54) LCD DEVICE AND FIXING PIECE FOR LOCKING PCB

(71) Applicant: Guofu Tang, Shenzhen (CN)

(72) Inventor: Guofu Tang, Shenzhen (CN)

(21) Appl. No.: 13/578,165

(22) PCT Filed: Jul. 9, 2012
(86) PCT No.: PCT/CN12/78335

§ 371 Date: Aug. 9, 2012

(51) Int. Cl. H05K 7/02; H05K 5/03

(52) U.S. Cl. 361/759; 361/752; 403/291

(57) ABSTRACT

A liquid crystal display (LCD) device includes a backplane, a PCB fixed to the backplane, and a fixing piece used for fixing the PCB. The fixing piece includes a main trunk, and limit parts arranged at two ends of the main trunk. The limit parts are made of insulating material. In the present disclosure, because the limit parts arranged at the two ends of the fixing piece for fixing the PCB are made of insulating material, a domain of the PCB covered by the limit parts can still be wired by only bypassing the fixing hole. Meanwhile, the limit parts made of insulating material are not required to be laid with copper near a fixing hole, and an area of the PCB is reduced.

### TECHNICAL FIELD

The present disclosure relates to the field of liquid crystal displays (LCDs), and more particularly to an LCD device and a fixing piece for locking a printed circuit board (PCB).

### BACKGROUND

Liquid crystal display (LCD) control signals of LCDs are input by printed circuit boards (PCBs). Because frames of the LCDs are narrow, PCBs are generally arranged on backs of backlight modules (namely backplanes), and PCBs are usually locked and fixed by screws.

As shown in FIG. 1, an LCD includes an LCD panel 10, and a backlight module. A PCB 30 used for controlling liquid crystal is arranged on a backplane 20 of the backlight module, the LCD panel 10 is connected with the PCB 30 by a chip on film (COF) 34, and the PCB 30 is directly locked and fixed to the backplane 20 by a screw 31. As shown in FIG. 2, the disadvantage of using the screw 31 for fixing is that a diameter of the screw cap occupies space of the PCB 30. The occupied space is shown as an oblique line domain 7 in the Figure. The oblique line domain 7 is more than the diameter of the screw cap in general, and other circuits cannot be laid in the oblique line domain 7. A circuit 33 needs to bypass the overall oblique line domain 7 to avoid contacting the screw cap to affect normal operation of the PCB 30. In addition, copper is also generally laid in the oblique line domain to be grounded. An area of the oblique line domain is added when laying the copper, thereby disadvantaging the area reduction of the PCB 30, adding manufacturing cost of the PCB30, and disadvantaging compaction and optimization of an internal structure of the LCD.

### SUMMARY

In view of the above-described problems, the aim of the present disclosure is to provide a low-cost liquid crystal display (LCD) device, and a fixing piece for locking a printed circuit board (PCB).

The aim of the present disclosure is achieved by the following technical scheme.

An LCD device comprises a backplane, a PCB fixed to the backplane, a fixing piece used for fixing the PCB, and a cover plate used for covering the PCB. The fixing piece comprises a main trunk, and two layers of insulating blocking pieces which are respectively arranged at two ends of the main trunk. The insulating blocking pieces arranged at the two ends of the main trunk are insulating blocking pieces with flexible elasticity. The fixing piece penetrates through the PCB and the backplane and locks the backplane and the PCB together respectively from the two ends by the insulating blocking pieces arranged at the two ends of the main trunk. One end of fixing piece corresponding to the cover plate is configured with a protrusion, and a top of the protrusion is configured with an annular protrusion edge with the diameter larger than the diameter of the protrusion. The other end of the fixing piece is also configured with a protrusion, and the protrusion is a part of the main trunk protruding from the insulating blocking pieces.

The aim of the present disclosure is further achieved by the following technical scheme. An LCD device comprises a backplane, a PCB fixed to the backplane, and a fixing piece used for fixing the PCB. The fixing piece comprises a main trunk, and limit parts arranged at two ends of the main trunk; the limit parts are made of insulating material.

In one example, the limit parts are insulating blocking pieces which are respectively arranged at two ends of the main trunk. The insulating blocking pieces arranged at least at one end of the main trunk are insulating blocking pieces with flexible elasticity. The fixing piece penetrates through the PCB and the backplane and locks the backplane and the PCB together respectively from the two ends by the insulating blocking pieces arranged at the two ends of the main trunk. When the PCB is attached and fixed, the end of the fixing piece is inserted in a fixing hole of the PCB. Because the insulating blocking pieces have flexible elasticity, when being inserted, the insulating blocking pieces elastically deform and penetrate through the fixing hole of the PCB and a mounting hole of the backplane. When passing a thickness of the mounting hole of the backplane, the insulating blocking pieces restore to an original shape, and the diameter of the insulating blocking pieces is more than the diameter of the fixing hole of the PCB and the mounting hole of backplane. At this moment, the PCB and the backplane are positioned between the insulating blocking pieces arranged at the two ends of the fixing piece.

In one example, all the insulating blocking pieces arranged at the two ends of the main trunk of the fixing piece are insulating blocking pieces with flexible elasticity. The fixed PCB and backplane have certain buffer performance and cannot be locked up because the two ends of the main trunk are configured with insulating blocking pieces with flexible elasticity.

In one example, the backplane is further configured with a cover plate used for covering the PCB, and one end of the fixing piece corresponding to the cover plate is configured with a protrusion. A limit structure is formed by the protrusion at one end of the fixing piece, to prevent the cover plate from butting with components of the PCB because of deformation, and the protrusion can facilitate removal and installation of the fixing piece.

In one example, the top of the protrusion is configured with an annular protrusion edge with the diameter more than the diameter of the protrusion. The fixing piece can be more conveniently removed by using the annular protrusion edge.

Preferably, the other end of the fixing piece is also configured with a protrusion, and the protrusion is a part of the main trunk protruding from the insulating blocking pieces. The other end is also configured with the protrusion, and the protrusion is configured with a chamfer, to facilitate the insertion of the fixing piece into the PCB and the backplane.

In one example, the fixing piece is integratedly made of rubber material. Rubber has high elasticity and flexibility. The main trunk and the insulating blocking pieces of the fixing piece can be separately made and then fixed together. However, a manufacturing process can be reduced when the fixing piece is integratedly made.

A fixing piece for locking a PCB, the fixing piece comprises a main trunk, and limit parts arranged at both ends of the main trunk. The limit parts are made of insulating material.

In one example, the limit parts are insulating blocking pieces which are respectively arranged at both ends of the main trunk. The insulating blocking pieces arranged at least at one end of the main trunk are insulating blocking pieces with flexible elasticity. The fixing piece penetrates through the PCB and a position of the PCB to be fixed, and locks the PCB and the position of the PCB to be fixed together respectively from the two ends by the insulating blocking pieces arranged at the two ends of the main trunk. By taking the fixation of the PCB of the LCD device as an example, when the PCB is attached and fixed, the end of the fixing piece is inserted in a fixing hole of the PCB. Because the insulating blocking pieces have flexible elasticity, when being inserted, the insulating blocking pieces elastically deform and penetrate through the fixing hole of the PCB and the mounting hole of the backplane. When passing the thickness of the mounting hole of the backplane, the insulating blocking pieces restore to the original shape, and the diameter of the insulating blocking pieces is more than the diameter of the fixing hole of the PCB and the mounting hole of backplane. At this moment, the PCB and the backplane are positioned between the insulating blocking pieces arranged at the two ends of the fixing piece.

In the present disclosure, because the limit parts arranged at the two ends of the fixing piece used for fixing the PCB are made of insulating material, the domain of the PCB covered by the limit parts can still be wired by only bypassing the fixing hole. Meanwhile, the limit parts made of insulating material are not required to be laid with copper near the fixing hole, and the area of the PCB is saved. Thus, a width of the PCB is reduced, the production cost of the LCD device is saved, and the internal structure design of the LCD device is optimized.

### BRIEF DESCRIPTION OF FIGURES

FIG. 1 is a structure diagram of a locking mode of a PCB of a typical LCD device.

FIG. 2 is a structure diagram of laying copper and wiring on a PCB when locking the PCB by a screw in the prior art.

FIG. 3 is a structure diagram of fixing a PCB by a fixing piece of an example of the present disclosure.

FIG. 4 is a structure diagram of wiring on a PCB when locking the PCB by a fixing piece of an example of present disclosure.

FIG. 5 is a simplified structure diagram of a fixing piece of an example of the present disclosure.

FIG. 6 is another improved simplified structure diagram of a fixing piece of an example of the present disclosure; and

FIG. 7 is a simplified structure diagram of a fixing piece with single insulating blocking pieces of an example of the present disclosure.

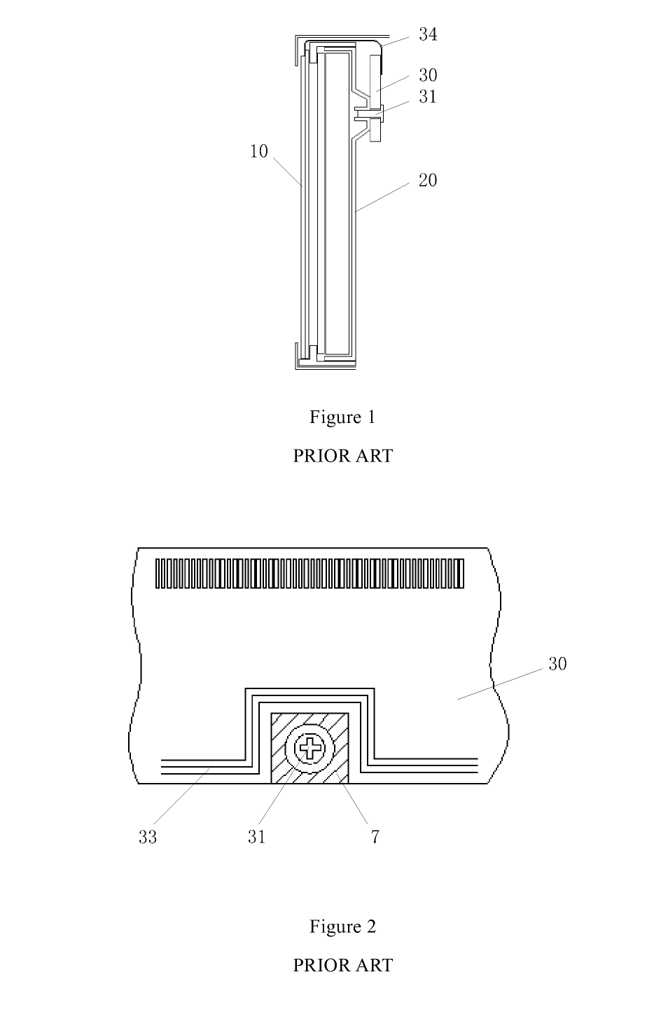

Legends: 10. LCD panel; 20. backplane; 30. PCB; 31. screw; 32. fixing piece; 34. COF; 320. main trunk; 321. first insulating blocking piece; 322. second insulating blocking piece; 323. protrusion; 324. protrusion.

### DETAILED DESCRIPTION

The present disclosure will be further described in accordance with the Figures and preferred examples.

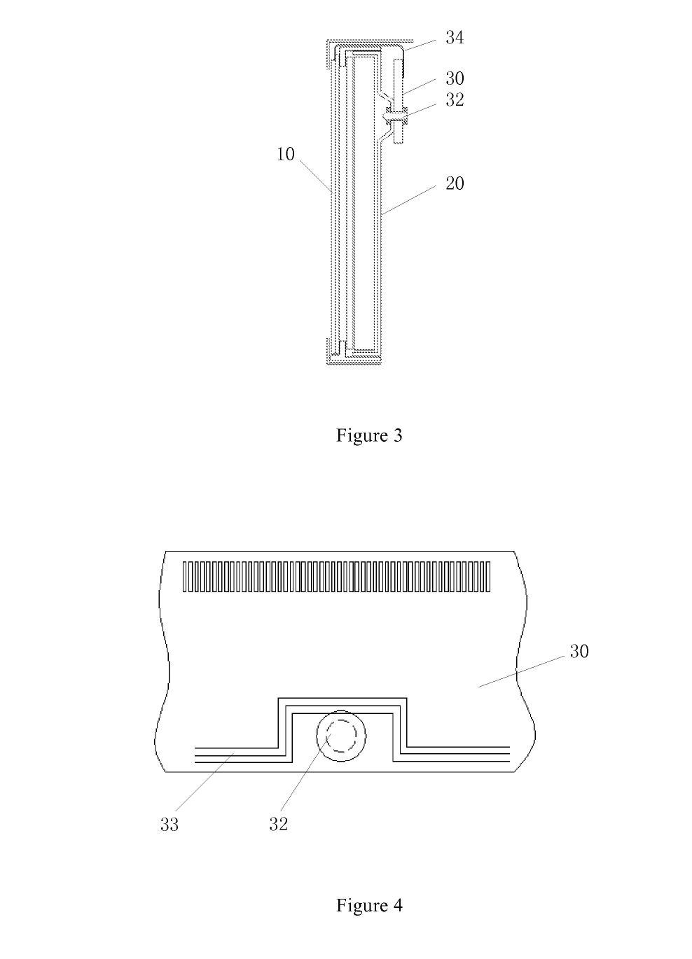

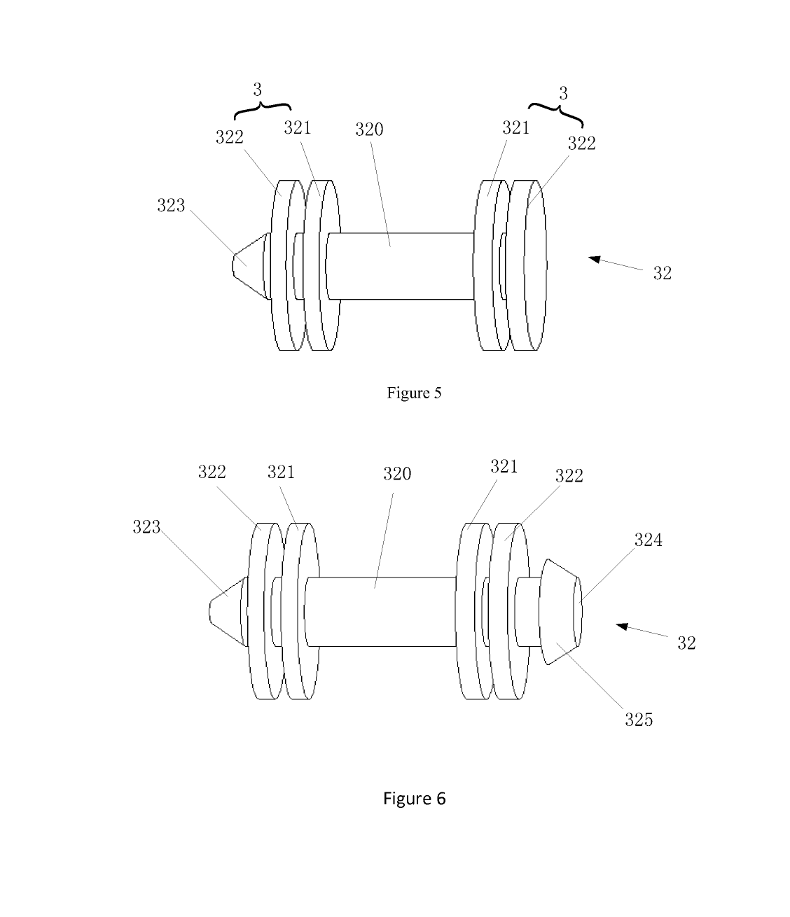

FIG. 3 shows a specific example of the present disclosure. A liquid crystal display (LCD) device comprises an LCD panel 10, and a backlight module. A printed circuit board (PCB) 30 used for driving the LCD panel 10 is arranged on a backplane 20 of the backlight module, and the PCB 30 is connected with the LCD panel 10 by a chip on film (COF) 34. The PCB 30 is fixed to the backplane 20 of the backlight module by a fixing piece 32. As shown in FIG. 5, the fixing piece 32 comprises a main trunk 320, and limit parts (first insulating blocking pieces 321 and second insulating blocking pieces 322) arranged at two ends of the main trunk. As shown in FIG. 4, because the limit parts are made of insulating material, a domain of the PCB covered by the limit parts can still be wired, and a circuit 33 can be covered by the limit parts of the fixing piece 32 if only the circuit 33 bypasses the fixing hole. Meanwhile, the limit parts made of insulating material are not required to be laid with copper near the fixing hole, and an area of the PCB is saved. Thus, a width of the PCB is reduced, production cost of the LCD device is saved, and an internal structure design of the LCD device is optimized. Therefore, an assembly volume of the LCD device is smaller, and configuration between assemblies is more compact and reasonable.

As shown in FIG. 5, the limit parts arranged at the two ends of the main trunk 320 of the fixing piece 32 are respectively the first insulating blocking pieces 321 and the second insulating blocking pieces 322. A distance between the two first insulating blocking pieces 321 is less than the distance between the two second insulating blocking pieces 322. The first insulating blocking pieces 321 and the second insulating blocking pieces 322 are made of material with flexible elasticity. As shown in FIG. 3, when the PCB 30 is attached and fixed, an end of the fixing piece 32 is inserted in the fixing hole of the PCB 30. In accordance with FIG. 5, because the insulating blocking pieces have flexible elasticity, when being inserted, the first insulating blocking pieces 321 and the second insulating blocking pieces 322 elastically deform and penetrate through the fixing hole of the PCB 30 and a mounting hole of the backplane 20. When the fixing pieces pass a thickness of the mounting hole of the backplane, the first insulating blocking pieces 321 and the second insulating blocking pieces 322 restore to an original shape, and the diameter of the insulating blocking pieces is more than the diameter of the fixing hole of the PCB 30 and the mounting hole of backplane 20. At this moment, the PCB 30 and the backplane 20 are positioned between the insulating blocking pieces arranged at the two ends of the fixing piece, namely the fixing pieces 32 penetrate through the PCB 30 and the backplane 20 and lock the backplane 20 and the PCB 30 together respectively from the two ends by the insulating blocking pieces arranged at the two ends (the first insulating blocking pieces 321 and the second insulating blocking pieces 322). Thus, the fixing piece 32 can be directly and manually assembled without using additional tools.

When meeting the condition of arranging the PCB 30, only one end of the fixing piece 32 can be configured with insulating blocking pieces with flexible elasticity, while the other end can be configured with insulating blocking pieces without flexible elasticity. Because only one end of the fixing piece is inserted when installing, the other end is not squeezed and deformed. However, in the example, all the insulating blocking pieces arranged at the two ends of the fixing piece 32 are insulating blocking pieces with flexible elasticity. Thus, as shown in FIG. 3, the fixed PCB 30 and backplane 20 have certain buffer performance and cannot be locked up. Optionally, the main trunk 320 is better configured with certain elasticity. When the LCD device is vibrated, such as vibration test, in the vibration process, a reacting force of the COF 34 can generate a horizontal pulling force to the PCB 30 when the COF 34 is enforced by the pulling force of the LCD panel 10, and elastic deformation can be generated because the fixing piece 32 has flexible elasticity. Therefore, partial pulling force of the COF 34 can be absorbed, and then the COF cannot be in a tightening state. Thus, friction of the COF can be reduced, bad image phenomena such as bright line and the like which are caused by circuit failure because the COF is rubbed and scratched by foreign matter can be avoided, and the COF cannot be damaged through the elastic fixing piece 32 when generating horizontal pulling force because of external force. A length of the COF is not required to be added, and the production cost is saved.

The fixing piece of the example is integratedly made of rubber material. Rubber has high elasticity and flexibility. Optionally, the main trunk 320 and the insulating blocking pieces of the fixing piece 32 can be separately made and then fixed together. However, the manufacturing process can be reduced when the fixing piece is integratedly made. In addition, the fixing piece made of rubber material is cheaper than a screw made of metal material, thereby saving the production cost of the LCD device.

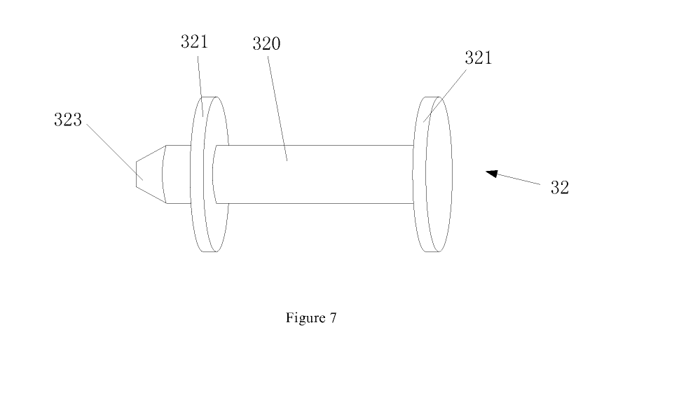

When meeting the condition of locking the PCB 30, as shown in FIG. 7, the fixing piece 32 can only be configured with the first insulating blocking pieces 321 without being configured with the second insulating blocking pieces. However, arranging the second insulating blocking pieces enable the fixing piece 32 to still have the locking function under the condition that the first insulating block pieces 321 fail when being damaged.

As show FIG. 5, the inserted end of the fixing piece is configured with a protrusion 323. The protrusion 323 is a part of the main trunk 320 of the fixing piece 32 protruding from the first insulating blocking piece 321 and the second insulating blocking piece 322. Moreover, the protrusion 323 is configured with a chamfer which facilitates the easier insertion of the fixing piece 32 into the holes of the PCB and the backplane.

As shown in FIG. 3, in the example, the backplane 20 of the LCD device is further configured with a cover plate (not shown in the Figure) used for covering the PCB 30. FIG. 6 shows an improvement of the example. The non-inserted end of the fixing piece 32 is also configured with a protrusion 324. A limit structure is formed by the protrusion 324, to prevent the cover plate from butting with the components of the PCB 30 because of deformation and protect the PCB 30, and the protrusion 324 can facilitate removal or installation of the fixing piece 32. A top of the protrusion 324 is configured with an annular protrusion edge 325 with the diameter more than the diameter of the protrusion 324. The fixing piece 32 is more conveniently taken out by using the annular protrusion edge 325.

Optionally, for the present disclosure, the fixing piece can lock the PCB arranged on the backplane, and can also lock the PCB arranged in other position of the LCD device. If the PCB is arranged on the back cover of the LCD device, the fixing piece of the present disclosure can also be used.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. An liquid crystal display (LCD) device, comprising:
a backplane,
a printed circuit board (PCB) fixed to the backplane,
a fixing piece used for fixing the PCB, and
a cover plate used for covering the PCB;
wherein the fixing piece comprises a main trunk, and two layers of insulating blocking pieces which are respectively arranged at two ends of the main trunk;
wherein the insulating blocking pieces arranged at the two ends of the main trunk are insulating blocking pieces with flexible elasticity, and the fixing piece penetrates through the PCB and the backplane and locks the backplane and the PCB together respectively from the two ends by the insulating blocking pieces arranged at the two ends of the main trunk; and
wherein one end of the fixing piece corresponding to the cover plate is configured with a protrusion, and a top of the protrusion is configured with a annular protrusion edge with a diameter more than the diameter of the protrusion; the other end of the fixing piece is also configured with a protrusion, and the protrusion is a part of the main trunk protruding from the insulating blocking pieces.

2. An liquid crystal device (LCD) device, comprising:
a backplane,
a printed circuit board (PCB) fixed to the backplane, and
a fixing piece used for fixing the printed circuit board (PCB);
wherein the fixing piece comprises a main trunk, and limit parts arranged at two ends of the main trunk; the limit parts are made of insulating material.

3. The LCD device of claim 2, wherein the limit parts are insulating blocking pieces which are respectively arranged at two ends of the main trunk; the insulating blocking pieces arranged at one end of the main trunk are insulating blocking pieces with flexible elasticity;
the fixing piece penetrates through the PCB and the backplane and locks the backplane and the PCB together respectively from the two ends by the insulating blocking pieces arranged at the two ends of the main trunk.

4. The LCD device of claim 3, wherein all the insulating blocking pieces arranged at the two ends of the main trunk of the fixing piece are insulating blocking pieces with flexible elasticity.

5. The LCD device of claim 4, wherein Two ends of the fixing piece are respectively configured with two layers of flexible insulating blocking pieces.

6. The LCD device of claim 3, wherein the backplane is further configured with a cover plate used for covering the PCB, and one end of the fixing piece corresponding to the cover plate is configured with a protrusion.

7. The LCD device of claim 6, wherein a top of the protrusion is configured with an annular protrusion edge with the diameter more than the diameter of the protrusion.

8. The LCD device of claim 6, wherein the other end of the fixing piece is also configured with a protrusion, and the protrusion is a part of the main trunk protruding from the insulating blocking pieces.

9. The LCD device of claim 3, wherein the fixing piece is integratedly made of rubber material.

10. A fixing piece for locking a printed circuit board (PCB), comprising:
a main trunk, and
limit parts arranged at two ends of the main trunk;
wherein the limit parts are made of insulating material.

11. The fixing piece for locking a PCB of claim 10, wherein the limit parts are insulating blocking pieces which are respectively arranged at two ends of the main trunk; the insulating blocking pieces arranged at least at one end of the main trunk are insulating blocking pieces with flexible elasticity; the fixing piece penetrates through the PCB and the backplane of the LCD device and locks the backplane and the PCB together respectively from the two ends by the insulating blocking pieces arranged at the two ends.

12. The fixing piece for locking a PCB of claim 11, wherein all the insulating blocking pieces arranged at the two ends of the main trunk of the fixing piece are insulating blocking pieces with flexible elasticity.

13. The fixing piece for locking a PCB of claim 12, wherein two ends of the fixing piece are respectively configured with two layers of flexible insulating blocking pieces.

14. The fixing piece for locking a PCB of claim 11, wherein the backplane is further configured with a cover plate used for covering the PCB, and one end of the fixing piece corresponding to the cover plate is configured with a protrusion.

15. The fixing piece for locking a PCB of claim 14, wherein the top of the protrusion is configured with an annular protrusion edge with the diameter more than the diameter of the protrusion.

16. The fixing piece for locking a PCB of claim 14, wherein the other end of the fixing piece is also configured with a protrusion, and the protrusion is a part of the main trunk protruding from the insulating blocking pieces.

17. The fixing piece for locking a PCB of claim 11, wherein the fixing piece is integratedly made of rubber material.
